(19) United States
(12) Patent Application Publication
(10) Pub. No.: US 2012/0018521 A1
(43) Pub. Date: Jan. 26, 2012

(54) OBJECT CARRIER HAVING A DATA MEMORY

(76) Inventor: Fabio Insalata, Braunschweig (DE)

(21) Appl. No.: 13/144,320

(22) PCT Filed: Jan. 7, 2010
(86) PCT No.: PCT/EP2010/000042

§ 371 Date: Sep. 30, 2011

(30) Foreign Application Priority Data
Jan. 16, 2009 (DE) 10 2009 005 307.7

(51) Int. Cl. G06K 19/077; H05K 3/30

(52) U.S. Cl. 235/492; 29/841

(57) ABSTRACT

The invention relates to object carriers (1), in particular for microscopy or analysis technology, having at least one information means (6). Starting from this point, an object carrier that is improved with regard to practical suitability in laboratory operation and a method for the production thereof are specified. For this purpose, a recess (5), in which the information means (6) is arranged, is provided in the object carrier (1).

The invention relates to an object carrier, in particular for microscopy or analysis technology, having at least one information means. The invention also relates to a method for producing such an object carrier.

An object carrier of the generic type is known for example from DE 10 2004 024 145 A1.

In the case of the known object carrier, a data carrier is placed on the surface. Such data carriers are stuck, for example in the form of an RFID element, for example as a label, on the object carrier, which usually consists of glass.

The known way of providing an object carrier with a data carrier has the disadvantage that said data carrier can relatively easily be lost, for example if the adhesive on the label loses its adhesive force. In addition, the label can be damaged in laboratory operation. As a result, the function of the data carrier can be impaired or the data carrier can be lost.

The invention is based on the object of specifying an object carrier which is improved with respect to practical suitability in laboratory operation and also a method for producing said object carrier.

This object is achieved by the object carrier specified in claim 1 and by the method specified in claim 13. Advantageous developments of the invention are specified in the dependent claims.

The invention makes it possible in an advantageous manner to embed the information means entirely or partially in the object carrier. As a result, the information means can be placed on the object carrier in a manner which is less susceptible to damage. The arrangement of the information means in a cutout in the object carrier has the further advantage that a mechanically more robust and longer-lasting connection to the object carrier can be achieved, for example by adhesively bonding the information carrier on more than one side in the cutout or by potting with a potting compound.

The information means, which is advantageously in the form of an electronic component, is enclosed in the cutout in the object carrier on four or five sides by the material of the object carrier. Thus, only one or two sides remain in which no material of the object carrier is present. The electronic component can be covered with the potting compound from these sides.

According to an advantageous development of the invention, the information means is arranged entirely in the cutout in the object carrier. This makes it possible in an advantageous manner to embed the information means entirely in the object carrier, with the result that the surface is aligned on all sides with no elevations. This has the advantage that the geometry of the object carrier is not altered by the information means. One advantage is in particular that the external dimensions of the object carrier are not increased. As a result, the object carrier according to the invention is in practice particularly pleasant to handle and can be stacked easily. In addition, the information means is protected particularly well against damage or loss on account of external influences.

The arrangement of the information means in a cutout in the object carrier has the further advantage that a mechanically more robust and longer-lasting connection to the object carrier can be achieved, for example by adhesively bonding the information carrier on more than one side in the cutout or by potting with a potting compound.

In principle, it is possible for the cutout to penetrate the object carrier entirely or partially. The invention includes the possibility that the cutout is provided at any desired point on the object carrier, if appropriate also at a number of points, for example in the central region or laterally.

According to the invention, the cutout only partially penetrates the object carrier, and so material remains on one side of the object carrier and forms a bottom of the cutout. As a result, the information means can be arranged and secured in the cutout relatively easily and quickly without it having to be fixed in a complicated manner. In particular, the information means cannot drop through the cutout during the securing operation. Advantageously, the securing means, e.g. adhesive, can be distributed over the bottom region, so that a relatively large adhesive surface is available and secure adhesive bonding of the information means is enabled.

According to an advantageous development of the invention, the cutout is provided laterally on the object carrier. As a result, the cutout can be produced using commercially available machines and method steps, for example by lateral milling using a cylindrical milling cutter. In a particularly advantageous manner, the cutout can be milled into the object carrier from the side. A further advantage of this arrangement of the cutout is that the information means is provided outside the object region of the object carrier, in which region an object to be examined can be arranged, and so the information means does not impair the handling in practice of the object carrier.

According to a further advantageous configuration of the invention, the cutout is provided laterally in the object carrier in the manner of a pocket. The cutout can be produced for example by lateral milling using a relatively short, cylindrical milling cutter or by grinding using a grinding disk. One advantage in this case is that, once it has been introduced into the object carrier, the information means is already surrounded on five sides by the material of the object carrier, as a result of which the information means is protected particularly well against external influences. In addition, this additionally makes it easier to secure the information means in the object carrier. In order to protect the information means entirely against environmental influences, all that is required is to close one side, for example using a potting compound.

In principle, information means of any desired kind can be used as information means, for example carrier materials having a barcode which can be configured in a one-dimensional or two-dimensional manner. Advantageously, a hologram or any other kind of optical information means can also be used as information carrier. Advantageously, the information means allows unambiguous identification of the object carrier or of a series of object carriers.

According to the invention, an electronic component is used as the information means. This has the advantage that relatively large amounts of data can be stored on the information means even at the current level of microelectronics. In addition, depending on the configuration of the electronic component, for example with a flash memory, an item of information to be entered can be altered multiple times and read as often as desired during operation of the object carrier.

According to an advantageous development of the invention, the electronic component is configured for wireless transfer of information. Compared with optical information means, this results in less susceptibility to soiling. In this connection, it is advantageous to use a component having a transponder. This has the advantage that it is possible to dispense with a separate power supply for the information means and no changing of batteries is necessary. In addition, a lifetime of the information means which is unlimited in practice can be achieved. According to an advantageous development, the electronic component can have an RFID element. RFID is an abbreviation for Radio Frequency Identification Device. This is a standard component for which an infrastructure in the form of readers and evaluation devices already exists. This has the advantage that the object carrier according to the invention can be designed to be compatible with already existing infrastructure in laboratories.

The invention further includes any kind of production steps for producing the cutout. For example, the cutout can be formed in the object carrier while the latter is still being produced, for example by giving the production mold an appropriate shape. Advantageously, the cutout can also be produced after the production of the object carrier blank by means of a material-removing production method, with methods such as milling, lasering or grinding being advantageous. The invention further includes any kind of securing of the information means in the cutout, for example clamping or latching securing, and also any kind of securing means. Securing by means of adhesive in the cutout in the object carrier is advantageous. A light-curing adhesive, for example, can advantageously be used. In this case, the adhesive can be cured at a desired point in time, for example by irradiation with ultraviolet or other light. Up until then, it is possible to orient the information means precisely in the cutout.

In principle, it is possible for the information means to be arranged in the cutout without any special covering. According to the invention, it is provided to cover the information means at least partially with a potting compound in the cutout, for example with synthetic resin. This can ensure particularly good protection of the information means against environmental influences. It is also advantageous also to use the securing means as covering means, or vice versa to use the covering means as securing means. It is likewise advantageous to apply the securing means and/or the covering means such that it is substantially aligned with the surfaces of the object carrier or at least does not protrude therefrom, so that the geometry of the object carrier is maintained. The potting compound used as covering means is advantageously resistant to chemicals which are used in laboratory analysis. It is advantageous to use as potting compound an acrylate, e.g. Vitralit. In an advantageous configuration of the invention, the potting compound covers the entire electronic component in the cutout.

The object carrier according to the invention can be produced from any desired material. It is advantageous to use an at least partially transparent material, in particular glass.

A method according to the invention for producing an object carrier includes the steps of:

a) producing an object carrier from at least one material,

b) forming a cutout in the material of the object carrier, in particular by milling, lasering and/or grinding,

c) placing a securing means in the cutout and/or on an information means,

d) placing the information means in the cutout,

e) curing the securing means.

In the case of clamping or latching securing, the placing of the securing means in the cutout can also advantageously be integrated into production step b), with the result that, for example, a protrusion for latching in the information means is also produced while the cutout is being formed.

Depending on the securing means used, it is possible for production steps c) and d) to take place simultaneously or in succession. If production step c) takes place before step d), it is advantageous, while an information means is being placed in the cutout, to arrange the information means on the securing means. If production step d) takes place before step c), it is advantageous to place the securing means such that the securing means connects the information means to the object carrier, e.g. by introducing the securing means into a gap between the cutout and the information means.

According to an advantageous development of the invention, cleaning of the object carrier takes place after step b). Further cleaning steps are likewise advantageous, e.g. removal of excess adhesive or excess potting compound.

According to an advantageous development of the invention, in step e) the object carrier is irradiated, in particular with ultraviolet light.

According to an advantageous development of the invention, before or after step e) the information means can be at least partially covered with a covering means, e.g. with synthetic resin of some other potting compound.

The invention is explained in more detail in the following text by way of exemplary embodiments and using drawings.

In the drawings:

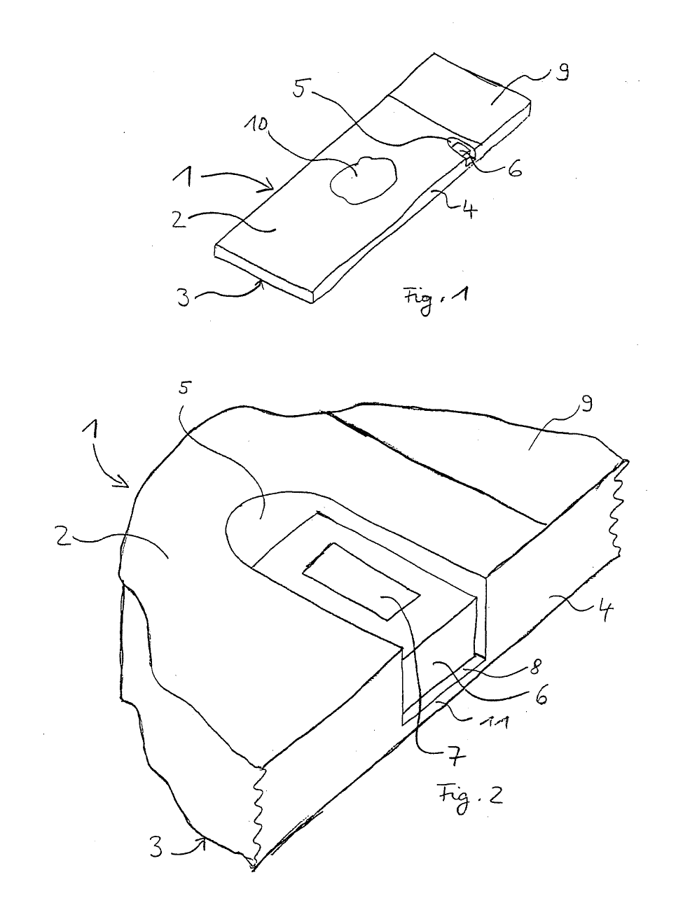

FIG. 1 shows a perspective view of an object carrier,

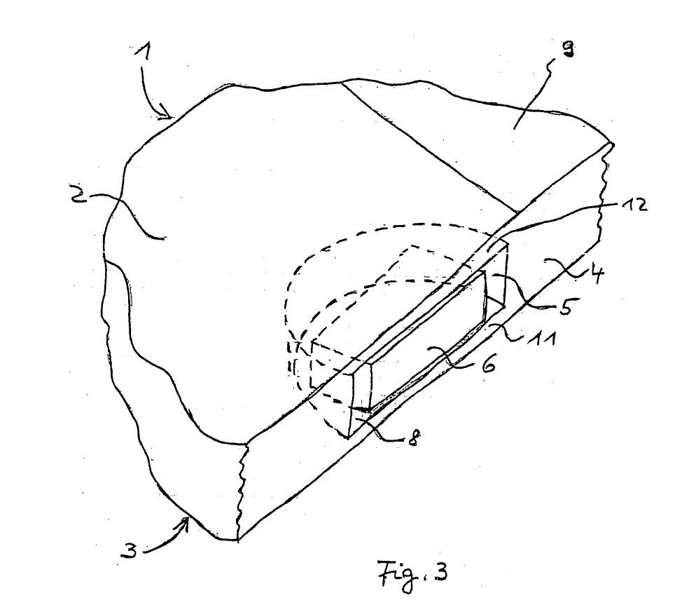

FIG. 2 shows an enlarged detail of the object carrier according to FIG. 1, and

FIG. 3 shows an enlarged detail of an object carrier having a cutout in a further embodiment.

In the figures, the same reference signs are used for elements that correspond to one another.

FIG. 1 shows an object carrier 1 which is produced from glass and has an elongate form having a substantially cuboidal shape. The object carrier 1 has a top side 2, on which an object to be examined 10 can be positioned. The object carrier 1 also has an underside 3 opposite the top side 2 and also peripheral lateral boundary surfaces 4. In a region 9 of the top side 2, the object carrier 1 has an inscription surface. The inscription surface of the object carrier can be provided by an applied color or by a material-removing surface treatment, e.g. by grinding or etching, of the object carrier in the region 9 of the inscription surface.

The object carrier 1 further has a laterally arranged cutout 5. The cutout can be produced for example by means of a cylindrical milling cutter, which is guided from one lateral boundary surface into the object carrier. Arranged in the cutout 5 is an information means 6. The information means 6 is arranged for example entirely in the cutout so that it does not project out of the object carrier.

That region of the object carrier 1 in which the cutout 5 is provided is illustrated as an enlarged detail in FIG. 2. As can be seen, the cutout 5 has a bottom surface 8, i.e. the cutout 5 does not penetrate the object carrier 1 entirely in the manner of a hole, but rather in the manner of a recess, and so a region 11 remains on the underside 3 and forms a bottom of the cutout 5. The information means 6, which has for example an RFID element 7, is secured by way of adhesive to the bottom surface 8 and if necessary also to the lateral surfaces of the cutout 5. In this embodiment, the information means 6 is surrounded on four sides in the cutout 5 by the material of the object carrier 1.

Illustrated in FIG. 3 is a similar detail of the object carrier 1 to that in FIG. 2, but with a further embodiment of the cutout 5. According to FIG. 3, the cutout 5 is formed in the manner of a pocket or cavity which is provided laterally in the object carrier 1. The cutout 5 can for example be produced by introducing a relatively short cylindrical milling cutter from one lateral boundary surface into the material of the object carrier. The milling cutter should in this case be selected to be shorter than the thickness of the object carrier, e.g. 30% shorter. In this case, regions 11, 12 remain on the top side 2 and underside 3 of the object carrier. The regions 11, 12 advantageously have a thickness of at least 20 μm.

The information means 6 is once again arranged in the cutout 5. In the exemplary embodiment according to FIG. 3, the information means 6 is surrounded on five sides in the cutout 5 by the material of the object carrier 1.

1. An object carrier (1), in particular for microscopy or analysis technology, having at least one electronic component (6) having a memory for data storage, wherein in the object carrier (1) there is provided a cutout (5) in which the electronic component (6) is arranged, wherein the cutout (5) only partially penetrates the object carrier (1) and the electronic component is covered with a potting compound in the cutout (5).

2. The object carrier as claimed in claim 1, wherein the electronic component (6) is arranged entirely in the cutout (5).

3. The object carrier as claimed in claim 1, wherein the cutout (5) is provided laterally on the object carrier (1).

4. The object carrier as claimed in claim 1, wherein the cutout (5) is provided on a top side (2) of the object carrier (1), said top side (2) being provided to hold an object (10) to be examined.

5. The object carrier as claimed in claim 1, wherein the cutout (5) is provided laterally in the object carrier (1) in the manner of a pocket.

6. The object carrier as claimed in claim 1, wherein the electronic component is configured for wireless transfer of information and is provided in particular with a transponder.

7. The object carrier as claimed in claim 6, wherein the electronic component has an RFID element (7).

8. The object carrier as claimed in claim 1, wherein the cutout (5) is produced by using at least one of the methods of milling, lasering or grinding.

9. The object carrier as claimed in claim 1, wherein the information means (6) is secured in the cutout (5) in the object carrier (1) by a securing means, in particular adhesive.

10. A method for producing an object carrier, having the steps of:
a) producing an object carrier (1) from at least one material,
b) forming a cutout (5) in the material of the object carrier (1) such that the cutout (5) only partially penetrates the object carrier (1), in particular by milling, lasering and/or grinding,
c) placing a securing means in the cutout (5) and/or on an electronic component (6) which has a memory for data storage,
d) placing the electronic component (6) in the cutout (5),
e) covering the electronic component (6) with a potting compound,
f) curing the securing means and the potting compound.

11. The method as claimed in claim 10, including a further step of:
b1) cleaning the object carrier (1), after step b).

12. The method as claimed in claim 10, wherein in step f) the object carrier (1) is irradiated, in particular with ultraviolet light.
